(19) United States
(12) Patent Application Publication
(10) Pub. No.: US 2021/0328560 A1
(43) Pub. Date: Oct. 21, 2021

(54) INTEGRATED PHASE DIFFERENCE MEASUREMENT

(71) Applicant: Infineon Technologies AG, Neubiberg (DE)

(72) Inventors: Stefano DI MARTINO, Graz (AT); Philipp Franz FREIDL, Graz (AT)

(21) Appl. No.: 16/851,616

(22) Filed: Apr. 17, 2020

(51) Int. Cl. H03F 3/21; H03F 3/24; H03F 1/02

(52) U.S. Cl. CPC H03F 3/211; H03F 2200/451; H03F 1/0294; H03F 3/24

(57) ABSTRACT

A system may include a first power detector to measure a power level of a signal on a first transmitter channel, a second power detector to measure a power level of a signal on a second transmitter channel. The system may include a combiner to provide a combined signal associated with the signal on the first transmitter channel and the signal on the second transmitter channel, and a third power detector to measure a power level of the combined signal. The system may include a processing circuit to determine a relative phase difference between the signal on the first transmitter channel and the signal on the second transmitter channel based on results of measuring the power level of the signal on the first transmitter channel, measuring the power level of the signal on the second transmitter channel, and measuring the power level of the combined signal.

### BACKGROUND

A system, such as a radar system, may be include a set of transmit antennas and designed to transmit a signal and a set of receive antennas designed to receive (at least a portion of) the signal after the signal is reflected (e.g., by an object in an environment of the system). The system may output, based on the received signal, a signal for use in identifying a position of an object, a direction of the object, a speed of the object, and/or the like.

### SUMMARY

According to some implementations, a system may include a first power detector to measure a power level of a signal on a first transmitter channel; a second power detector to measure a power level of a signal on a second transmitter channel; a combiner to provide a combined signal associated with the signal on the first transmitter channel and the signal on the second transmitter channel; a third power detector to measure a power level of the combined signal; and a processing circuit to determine a relative phase difference between the signal on the first transmitter channel and the signal on the second transmitter channel, wherein the relative phase difference is determined based on a result of measuring the power level of the signal on the first transmitter channel, a result of measuring the power level of the signal on the second transmitter channel, and a result of measuring the power level of the combined signal.

According to some implementations, a method may include measuring a power level of a signal on a first transmitter channel; measuring a power level of a signal on a second transmitter channel; providing a combined signal associated with the signal on the first transmitter channel and the signal on the second transmitter channel; measuring a power level of the combined signal; and determining a relative phase difference between the signal on the first transmitter channel and the signal on the second transmitter channel based on a result of measuring the power level of the signal on the first transmitter channel, a result of measuring the power level of the signal on the second transmitter channel, and a result of measuring the power level of the combined signal.

According to some implementations, a system may include a combiner to provide a combined signal associated with a signal on a first transmitter channel and a signal on a second transmitter channel; a power detector to measure a power level of the combined signal; and a processing circuit to determine a relative phase difference between the signal on the first transmitter channel and the signal on the second transmitter channel, wherein the relative phase difference is determined based at least in part on a result of measuring the measured power level of the combined signal.

### BRIEF DESCRIPTION OF THE DRAWINGS

FIGS. 1A-1C are diagrams associated with an example system that performs integrated phase difference measurement, as described herein.

FIGS. 2A and 2B are graphical examples illustrating achievable error in relative phase difference determinations by a system when a 180° phase delay is imparted on a transmitter channel of the system, as described herein.

FIG. 3 is a flow chart of an example process relating to integrated phase difference measurement, as described herein.

### DETAILED DESCRIPTION

The following detailed description of example implementations refers to the accompanying drawings. The same reference numbers in different drawings may identify the same or similar elements.

In a system comprising a group of transmit antennas, a phase difference between a pair of transmitter channels may need to be monitored and/or controlled (e.g., in order to ensure acceptable performance of the system). For example, in a radar system including at least two antennas (e.g., a phased array to transmit a radar signal), a phase difference between a given pair of transmitter channels (e.g., a transmitter channel associated with a first transmit antenna and a transmitter channel associated with a second transmit antenna) should be monitored and/or controlled to, for example, ensure that a radar signal is transmitted in a desired direction. A prior technique for determining a phase difference between a pair of transmitter channels relies on direct conversion mixing of signals on the pair of transmitter channels. However, the direct conversion mixing technique involves use of an integrated mixer, which may consume a significant amount of die area and/or may be difficult to integrate and calibrate.

Some implementations described herein provide a system that enables integrated phase difference measurement. In some implementations, the system may include a first power detector to measure a power level of a signal on a first transmitter channel and a second power detector to measure a power level of a signal on a second transmitter channel. The system may further include a combiner to provide a combined signal associated with the signal on the first transmitter channel and the signal on the second transmitter channel, a third power detector to measure a power level of the combined signal, and a processing circuit to determine a relative phase difference between the signal on the first transmitter channel and the signal on the second transmitter channel. Here, the relative phase difference is determined based on a result of measuring the power level of the signal on the first transmitter channel, a result of measuring the power level of the signal on the second transmitter channel, and a result of measuring the power level of the combined signal. Notably, the first and second power detectors are generally included in a system designed to transmit signals on first and second transmitter channels and, therefore, the first and second power detectors do not increase complexity or cost of the system.

In some implementations, the system described herein enables a relatively simple and reliable measurement of a phase difference between signals associated with a pair of transmitter channels (e.g., signal of a same frequency or with a same modulation). In some implementations, the system described herein enables measurement of an average phase difference between two signals that are modulated with frequency modulated continuous wave (FMCW) ramps.

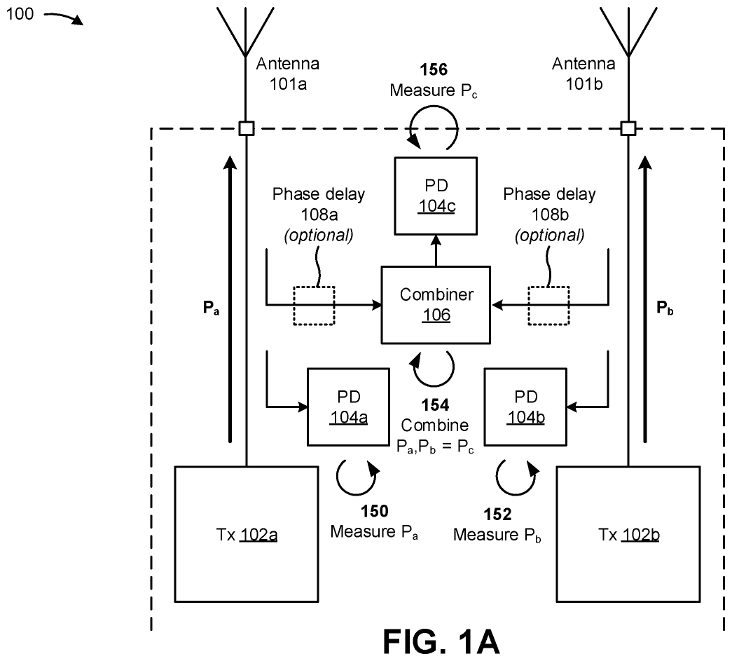

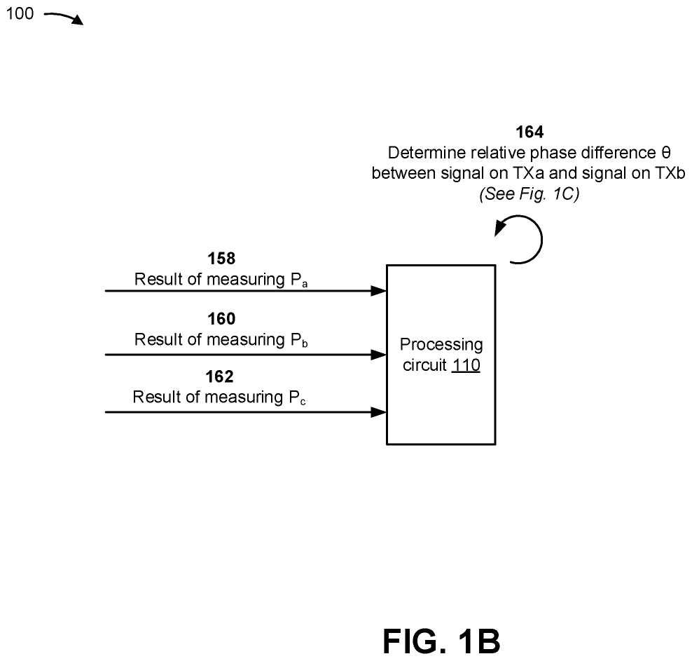

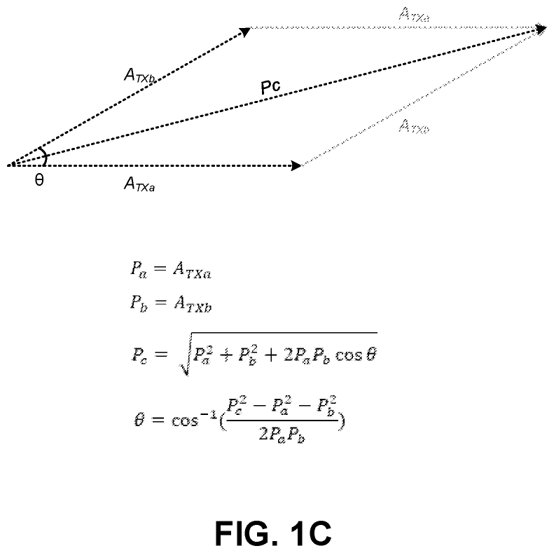

FIGS. 1A-1C are diagrams of an example system 100 that performs integrated phase difference measurement, as described herein. In some implementations, system 100 may be a radar system. As shown in FIGS. 1A and 1B, system 100 may include a group of antennas (e.g., including antenna 101a and antenna 101b), a group of transmitters (e.g., including Tx 102a and a Tx 102b), a group of power detectors (e.g., including PD 104a, PD 104b, and PD 104c), a combiner 106, a group of optional phase delay components (e.g., including phase delay 108a and phase delay 108b), and a processing circuit 110. Details of the components of system 100 are provided below, followed by a description of an example operation of system 100.

Antenna 101 is an antenna capable of transmitting a signal (e.g., a radio frequency (RF) signal, such as a radar signal) associated with a transmitter channel. In some implementations, the signal transmitted by antenna 101 is provided by a transmitter 102. For example, antenna 101a may be an antenna capable of transmitting a signal associated with a first transmitter channel, where the signal on the first transmitter channel is provided by Tx 102a. As another example, antenna 101b may be an antenna capable of transmitting a signal associated with a second transmitter channel, where the signal on the second transmitter channel is provided by Tx 102b.

Transmitter 102 includes a component capable of generating and/or providing a signal on a transmitter channel for transmission by antenna 101. For example, Tx 102a may be a component capable of generating and/or providing a signal on the first transmitter channel (e.g., such that the signal on the first transmitter channel may be transmitted by antenna 101a). As another example, Tx 102b may be a component capable of generating and/or providing a signal on the second transmitter channel (e.g., such that the signal on the second transmitter channel may be transmitted by antenna 101b). In some implementations, the signal provided by Tx 102a on the first transmitter channel and/or the signal on the second transmitter channel provided by Tx 102b may be modulated with FMCW ramps.

Power detector 104 is a component capable of measuring a power level of a signal. For example, PD 104a may be a component capable of measuring a power level of a signal on the first transmitter channel. As another example, PD 104b may be a component capable of measuring a power level of a signal on the second transmitter channel. As another example, PD 104c may be a component capable of measuring a power level of a combined signal provided by combiner 106, as described below. In some implementations, a given power detector 104 of system 100 may be configured to provide a result of measuring a power level of a signal to processing circuit 110.

Combiner 106 is a component capable of providing a combined signal associated with the signal on the first transmitter channel and the signal on the second transmitter channel. That is, combiner 106 may be configured to combine the signal on the first transmitter channel and the signal on the second transmitter channel, a result of which is the combined signal. In some implementations, combiner 106 may be configured to provide the combined signal to PD 104c (e.g., to allow PD 104c to measure the power level of the combined signal).

Phase delay component 108 is a component capable of imparting a phase delay on a signal on a transmitter channel. For example, phase delay 108a may be a component capable of imparting a phase delay on the signal on the first transmitter channel. In some implementations, when included in system 100, phase delay 108a may be arranged on a signal path between the first transmitter channel and combiner 106. As another example, phase delay 108b may be a component capable of imparting a phase delay on the signal on the second transmitter channel. In some implementations, when included in system 100, phase delay 108b may be arranged on a signal path between the second transmitter channel and combiner 106. As noted above, phase delay 108a and phase delay 108b are optional components of system 100, meaning that system 100 may include phase delay 108a only, phase delay 108b only, both phase delay 108a and phase delay 108b, or neither phase delay 108a or phase delay 108b.

In some implementations, phase delay component 108 may be implemented as a phase shifter, in a signal line (e.g., by increasing a length of the signal line), and/or the like. In some implementations, a phase delay imparted by phase delay component (e.g., phase delay 108a, phase delay 108b) may be a fixed phase delay, or may be a variable phase delay (e.g., a phase delay that can be controlled and/or adjusted).

Processing circuit 110 includes a component capable of determining a relative phase difference between signals on a pair of transmitter channels. For example, processing circuit may include a component capable of determining a relative phase difference between the signal on the first transmitter channel and the signal on the second transmitter channel in system 100. In some implementations, processing circuit 110 may be include one or more processors (e.g., one or more processors of a controller associated with system 100). Additionally, or alternatively, processing circuit 110 may be an integrated circuit of system 100 (e.g., a monolithic microwave integrated circuit (MMIC)).

In some implementations, processing circuit 110 may determine the relative phase difference based on a result of measuring the power level of the signal on the first transmitter channel, a result of measuring the power level of the signal on the second transmitter channel, and a result of measuring the power level of the combined signal. For example, by measuring the power levels of the signals on the first transmitter channel and the second transmitter channel using PD 104a and PD 104b, respectively, as well as a vector sum of the signals on the first transmitter channel and the second transmitter channel using PD 104c, an actual phase relation 0 between the signal on the first transmitter channel and the signal on the second transmitter channel can be derived from amplitude-only measurements on the first and second transmitter channels. This relationship is shown graphically illustrated in FIG. 1C. As indicated in in FIG. 1C, the power level of the signal on the first transmitter channel (Pₐ) is equal to an amplitude measurement of the signal on the first transmitter channel (A_{Txa}), the power level of the signal on the second transmitter channel (P_{b}) is equal to an amplitude measurement of the signal on the second transmitter channel (A_{Txb}), and therefore the relative phase difference (θ) should satisfy the following relationship:

P_{c}=\sqrt{Pₐ²+P_{b}²+2PₐP_{b} cos θ}

where P_{c} is the result of measuring the power level of the vector sum of the signal on the first transmitter channel and the second transmitter channel (i.e., the combined signal). Thus, in some implementations, processing circuit 110 may determine the relative phase difference between the signal on the first transmitter channel and the signal on the second transmitter channel based on the following relationship:

$$θ = {cos}^{- 1} ( \frac{{P}_{c}^{2} - {P}_{a}^{2} - {P}_{b}^{2}}{2 {P}_{a} {P}_{b}} )$$

In some implementations, processing circuit 110 may be configured to perform an action based at least in part on the relative phase difference. For example, processing circuit 110 may determine the relative phase difference, and may determine whether the relative phase difference satisfies a threshold (e.g., whether the relative phase difference is less than or equal to a maximum acceptable relative phase difference). Here, if processing circuit 110 determines that the relative phase difference satisfies a threshold, then processing circuit 110 may perform an action, such as providing an indication of an error associated with system 100, causing phase drift compensation to be performed for the first transmitter channel and/or the second transmitter channel, and/or the like.

Returning to FIG. 1A, an example operation of system 100 is provided. As shown by reference 150, PD 104a may measure a power level of a signal on the first transmitter channel (e.g., a signal provided by Tx 102a for transmission by antenna 101a). As shown by reference 152, PD 104b may measure a power level of a signal on the second transmitter channel (e.g., a signal provided by Tx 102b for transmission by antenna 101b). As shown by reference 154, combiner 106 may provide a combined signal associated with the signal on the first transmitter channel and the signal on the second transmitter channel, and may provide the combined signal to PD 104c. As shown by reference 156, PD 104c may measure a power level of the combined signal.

As shown by reference 158 in FIG. 1B, processing circuit 110 may receive, from PD 104a (e.g., after digitizing by an analog-to-digital converter (ADC)), a result of measuring the power level of the signal on the first transmitter channel. As shown by reference 160, processing circuit 110 may receive, from PD 104b (e.g., after digitizing by an ADC), a result of measuring the power level of the signal on the second transmitter channel. As shown by reference 162, processing circuit 110 may receive, from PD 104c (e.g., after digitizing by an ADC), a result of measuring the power level of the combined signal. As shown by reference 164, processing circuit 110 may then determine a relative phase difference between the signal on the first transmitter channel and the signal on the second transmitter channel based on the result of measuring the power level of the signal on the first transmitter channel, the result of measuring the power level of the signal on the second transmitter channel, and the result of measuring the power level of the combined signal (e.g., in the manner described above). In some implementations, processing circuit 110 may perform an action based on the determined phase difference, as described above.

In some implementations, the above described operations may be repeated (e.g., on a periodic basis) in order to provide monitoring and/or control of the phase difference between the signal on the first transmitter channel and the signal on the second transmitter channel.

As indicated above, FIGS. 1A-1C are provided as an example. Other examples may differ from what is described with regard to FIGS. 1A-1C. The number and arrangement of devices shown in FIGS. 1A-1C are provided as an example. In practice, there may be additional devices, fewer devices, different devices, or differently arranged than those shown in FIGS. 1A-1C. Furthermore, two or more devices shown in FIGS. 1A-1C may be implemented within a single device, or a single device shown in FIGS. 1A-1C may be implemented as multiple, distributed devices. Additionally, or alternatively, a set of devices (e.g., one or more devices) shown in FIGS. 1A-1C may perform one or more functions described as being performed by another set of devices shown in FIGS. 1A-1C.

As described above, in some implementations, system 100 may include one or more phase delay components 108. In some implementations, a phase delay component 108 may be designed to provide a phase delay to a signal on a transmitter channel. In some implementations, the phase shift may act to reduce an error associated with determining the relative phase difference between the signal on the first transmitter channel and the signal on the second transmitter channel. In some implementations, the phase delay may be used, for example, to set the relative phase difference between the signal on the first transmitter channel and the signal on the second at approximately 180°, while operating in a region in which power detector 104c has sufficient sensitivity to measure the power level of the combined signal with acceptable accuracy. With such a relative phase difference, the power level of the combined signal should be approximately equal to zero (e.g., 0 volts). This means that uncertainty on the relative phase difference will be reduced (e.g., since an error resulting from the measurement of the combined signal will have less weight). In practice, the phase delay and the setting for the desired relative phase difference may depend on the types of components used in system 100.

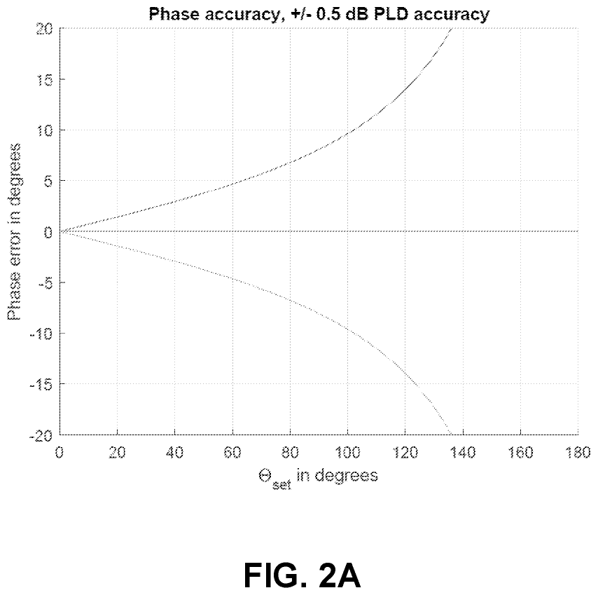

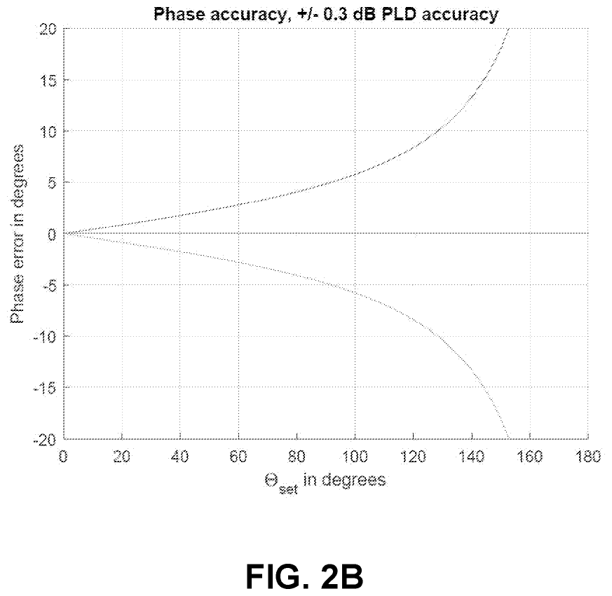

FIGS. 2A and 2B are graphical examples illustrating achievable error in relative phase difference determinations by system 100 when a 180° phase delay is imparted on a transmitter channel of system 100. As shown in FIG. 2A, with a ±0.5 decibel (dB) PLD accuracy, an absolute phase difference below 25° translates in an absolute error of less than or equal to approximately 2.5°. As shown in FIG. 2B, with a ±0.3 dB PLD accuracy, an absolute phase difference below 25° translates in an absolute error of less than or equal to approximately 1.0°.

As indicated above, FIGS. 2A and 2B are provided as examples. Other examples are possible than what is described with respect to FIGS. 2A and 2B. For example, results shown in FIGS. 2A and 2B are influenced by the type of power detectors and related components used in the system, and the use of other types of power detectors and/or other types of related components may yield different results.

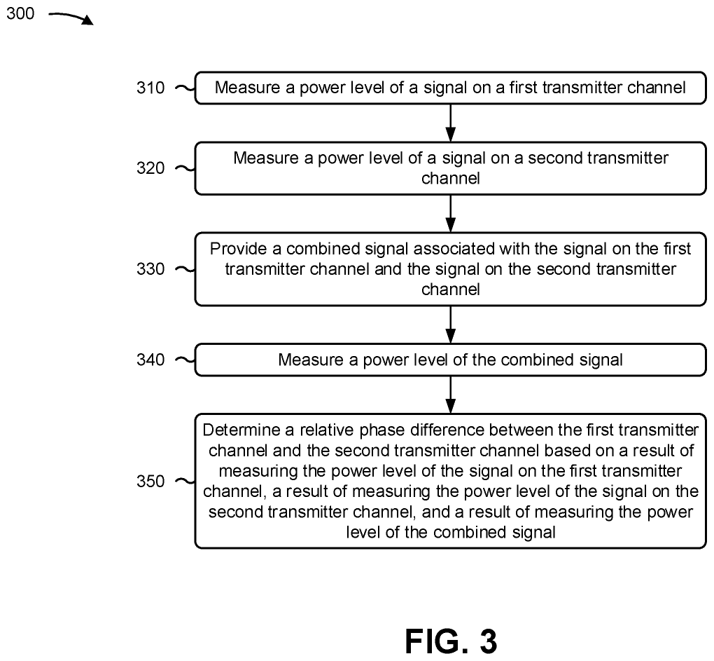

FIG. 3 is a flow chart of an example process 300 relating to integrated phase difference measurement, as described herein. In some implementations, one or more process blocks of FIG. 3 may be performed by a system (e.g., system 100).

As shown in FIG. 3, process 300 may include measuring a power level of a signal on a first transmitter channel (block 310). For example, the system (e.g., using power detector 104a and/or the like) may measure power level of a signal on a first transmitter channel, as described above.

As further shown in FIG. 3, process 300 may include measuring a power level of a signal on a second transmitter channel (block 320). For example, the system (e.g., using power detector 104b and/or the like) may measure power level of a signal on a second transmitter channel, as described above.

As further shown in FIG. 3, process 300 may include providing a combined signal associated with the signal on the first transmitter channel and the signal on the second transmitter channel (block 330). For example, the system (e.g., using combiner 106 and/or the like) may provide a combined signal associated with the signal on the first transmitter channel and the signal on the second transmitter channel, as described above.

As further shown in FIG. 3, process 300 may include measuring a power level of the combined signal (block 340). For example, the system (e.g., using power detector 104c and/or the like) may measure a power level of the combined signal, as described above.

As further shown in FIG. 3, process 300 may include determining a relative phase difference between the signal on the first transmitter channel and the signal on the second transmitter channel based on a result of measuring the power level of the signal on the first transmitter channel, a result of measuring the power level of the signal on the second transmitter channel, and a result of measuring the power level of the combined signal (block 350). For example, the system (e.g., using processing circuit 110) may determine a relative phase difference between the signal on the first transmitter channel and the signal on the second transmitter channel based on a result of measuring the power level of the signal on the first transmitter channel, a result of measuring the power level of the signal on the second transmitter channel, and a result of measuring the power level of the combined signal, as described above.

Process 300 may include additional implementations, such as any single implementation or any combination of implementations described below and/or in connection with one or more other processes described elsewhere herein.

In a first implementation, the relative phase difference is determined based on the relationship:

$$θ = {cos}^{- 1} ( \frac{{P}_{c}^{2} - {P}_{a}^{2} - {P}_{b}^{2}}{2 {P}_{a} {P}_{b}} )$$

wherein θ is the relative phase difference, Pₐ is the result of measuring the power level of the signal on the first transmitter channel, P_{b} is the result of measuring the power level of the signal on the second transmitter channel, and P_{c} is the result of measuring the power level of the combined signal.

In a second implementation, alone or in combination with the first implementation, process 300 further includes determining that the relative phase difference satisfies a threshold; and performing an action based on determining that the relative phase difference satisfies the threshold. The action may include, for example, providing an indication of an error or causing phase drift compensation, associated with the first transmitter channel or the second transmitter channel, to be performed.

In a third implementation, alone or in combination with any one or more of the first and second implementations, process 300 further includes imparting (e.g., using phase delay component 108a) a phase delay (e.g., a fixed phase delay or a variable phase delay) on the signal on the first transmitter channel on a signal path between the first transmitter channel and a combiner associated with providing the combined signal.

In a fourth implementation, alone or in combination with any one or more of the first through third implementations, process 300 further includes imparting (e.g., using phase delay component 108b) a phase delay (e.g., a fixed phase delay or a variable phase delay) on the signal on the second transmitter channel on a signal path between the second transmitter channel and the combiner.

In a fifth implementation, alone or in combination with any one or more of the first through fourth implementations, the signal on the first transmitter channel and the signal on the second transmitter channel are modulated with frequency modulated continuous wave ramps.

In a sixth implementation, alone or in combination with any one or more of the first through fifth implementations, the system is a radar system.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

The foregoing disclosure provides illustration and description, but is not intended to be exhaustive or to limit the implementations to the precise form disclosed. Modifications and variations may be made in light of the above disclosure or may be acquired from practice of the implementations.

As used herein, the term “component” is intended to be broadly construed as hardware, firmware, and/or a combination of hardware and software.

It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Some implementations are described herein in connection with thresholds. As used herein, satisfying a threshold may, depending on the context, refer to a value being greater than the threshold, more than the threshold, higher than the threshold, greater than or equal to the threshold, less than the threshold, fewer than the threshold, lower than the threshold, less than or equal to the threshold, equal to the threshold, etc., depending on the context.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A system, comprising:
a first power detector to measure a power level of a signal on a first transmitter channel;
a second power detector to measure a power level of a signal on a second transmitter channel;
a combiner to provide a combined signal associated with the signal on the first transmitter channel and the signal on the second transmitter channel;
a third power detector to measure a power level of the combined signal; and
a processing circuit to determine a relative phase difference between the signal on the first transmitter channel and the signal on the second transmitter channel,
wherein the relative phase difference is determined based on a result of measuring the power level of the signal on the first transmitter channel, a result of measuring the power level of the signal on the second transmitter channel, and a result of measuring the power level of the combined signal.

2. The system of claim 1, wherein the relative phase difference is determined based on a relationship:
$$θ = {cos}^{- 1} ( \frac{{P}_{c}^{2} - {P}_{a}^{2} - {P}_{b}^{2}}{2 {P}_{a} {P}_{b}} )$$
wherein θ is the relative phase difference, Pₐ is the result of measuring the power level of the signal on the first transmitter channel, P_{b} is the result of measuring the power level of the signal on the second transmitter channel, and P_{c} is the result of measuring the power level of the combined signal.

3. The system of claim 1, wherein the processing circuit is further to:
determine that the relative phase difference satisfies a threshold; and
perform an action based on determining that the relative phase difference satisfies the threshold.

4. The system of claim 3, wherein the action includes at least one of:
providing an indication of an error associated with the system; or
causing phase drift compensation, associated with the first transmitter channel or the second transmitter channel, to be performed.

5. The system of claim 1, further comprising:
a phase delay component to impart a phase delay on the signal on the first transmitter channel, the phase delay component being arranged on a signal path between the first transmitter channel and the combiner.

6. The system of claim 5, wherein the phase delay is a variable phase delay.

7. The system of claim 5, wherein the phase delay component is a first phase delay component, and wherein the system further comprises:
a second phase delay component to a impart phase delay on the signal on the second transmitter channel, the second phase delay component being arranged on a signal path between the second transmitter channel and the combiner.

8. The system of claim 1, wherein the signal on the first transmitter channel and the signal on the second transmitter channel are modulated with frequency modulated continuous wave ramps.

9. The system of claim 1, wherein the system is a radar system.

10. A method, comprising:
measuring a power level of a signal on a first transmitter channel;
measuring a power level of a signal on a second transmitter channel;
providing a combined signal associated with the signal on the first transmitter channel and the signal on the second transmitter channel;
measuring a power level of the combined signal; and
determining a relative phase difference between the signal on the first transmitter channel and the signal on the second transmitter channel based on a result of measuring the power level of the signal on the first transmitter channel, a result of measuring the power level of the signal on the second transmitter channel, and a result of measuring the power level of the combined signal.

11. The method of claim 10, wherein the relative phase difference is determined based on a relationship:
$$θ = {cos}^{- 1} ( \frac{{P}_{c}^{2} - {P}_{a}^{2} - {P}_{b}^{2}}{2 {P}_{a} {P}_{b}} )$$
wherein θ is the relative phase difference, Pₐ is the result of measuring the power level of the signal on the first transmitter channel, P_{b} is the result of measuring the power level of the signal on the second transmitter channel, and P_{c} is the result of measuring the power level of the combined signal.

12. The method of claim 10, further comprising:
determining that the relative phase difference satisfies a threshold; and
performing an action based on determining that the relative phase difference satisfies the threshold.

13. The method of claim 12, wherein the action includes at least one of:
providing an indication of an error; or
causing phase drift compensation, associated with the first transmitter channel or the second transmitter channel, to be performed.

14. The method of claim 10, further comprising:
imparting a phase delay on the signal on the first transmitter channel on a signal path between the first transmitter channel and a combiner associated with providing the combined signal.

15. The method of claim 14, further comprising:
imparting a phase delay on the signal on the second transmitter channel on a signal path between the second transmitter channel and the combiner.

16. The method of claim 10, wherein the signal on the first transmitter channel and the signal on the second transmitter channel are modulated with frequency modulated continuous wave ramps.

17. A system, comprising:
a combiner to provide a combined signal associated with a signal on a first transmitter channel and a signal on a second transmitter channel;
a power detector to measure a power level of the combined signal; and
a processing circuit to determine a relative phase difference between the signal on the first transmitter channel and the signal on the second transmitter channel,
wherein the relative phase difference is determined based at least in part on a result of measuring the measured power level of the combined signal.

18. The system of claim 17, wherein the power detector is a third power detector, and the system further comprises:
a first power detector to measure a power level of the signal on the first transmitter channel; and
a second power detector to measure a power level of the signal on the second transmitter channel,
wherein the relative phase difference is determined based at least in part on a result of measuring the power level of the signal on the first transmitter channel and a result of measuring the power level of the signal on the second transmitter channel.

19. The system of claim 18, wherein the relative phase difference is determined based on a relationship:
$$θ = {cos}^{- 1} ( \frac{{P}_{c}^{2} - {P}_{a}^{2} - {P}_{b}^{2}}{2 {P}_{a} {P}_{b}} )$$
wherein θ is the relative phase difference, Pₐ is the result of measuring the power level of the signal on the first transmitter channel, P_{b} is the result of measuring the power level of the signal on the second transmitter channel, and P_{c} is the result of measuring the power level of the combined signal.

20. The system of claim 17, further comprising:
a phase delay component to impart a phase delay on the signal on the first transmitter channel, the phase delay component being arranged on a signal path between the first transmitter channel and the combiner.
